(19) United States
(12) Patent Application Publication
(10) Pub. No.: US 2026/0114184 A1
(43) Pub. Date: Apr. 23, 2026

(54) LEAD ISOLATION SYSTEM AND METHOD FOR LEAD ZIRCONIUM TITANATE CERAMIC TRANSDUCER

(71) Applicant: PNEUMA RESPIRATORY, INC., Boone, NC (US)

(72) Inventors: Matthew Culpepper, Boone, NC (US); Caley Modlin, Boone, NC (US)

(73) Assignee: PNEUMA RESPIRATORY, INC., Boone, NC (US)

(21) Appl. No.: 18/997,398

(22) PCT Filed: Jul. 18, 2023
(86) PCT No.: PCT/US2023/028051

§ 371 Date: Jan. 21, 2025

Related U.S. Application Data
(60) Provisional application No. 63/390,228, filed on Jul. 18, 2022.

(51) Int. Cl. H10N 30/02; B08B 3/10; H10N 30/853

(52) U.S. Cl. CPC H10N 30/02; B08B 3/10; B08B 2240/00; H10N 30/8554

(57) ABSTRACT

A method of treating a lead zirconium titanate ceramic transducer, such as for use in droplet delivery devices, includes washing the lead zirconium titanate ceramic transducer with an HCl solution and coating the transducer with material that prevents lead from leaching into fluid contacting the transducer.

### FIELD

The present disclosure relates generally to droplet delivery devices including droplet delivery devices for the delivery of fluids that are inhaled into the mouth, throat, nose, and/or lungs.

### BACKGROUND

Current droplet delivery systems include a variety of inhaler type systems. Some examples are metered dose inhalers (MDI), pressurized metered dose inhalers (p-MDI), pneumatic devices, and ultrasonic-driven devices.

### DETAILED DESCRIPTION

As used herein, the terms “comprises,” “comprising,” “includes,” “including,” “has,” “having” or any other variation thereof, are intended to cover a non-exclusive inclusion. For example, a process, product, article, or apparatus that comprises a list of elements is not necessarily limited only those elements but can include other elements not expressly listed or inherent to such process, process, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The term substantially, as used herein, is defined to be essentially conforming to the particular dimension, shape or other word that substantially modifies, such that the component need not be exact. For example, substantially cylindrical means that the object resembles a cylinder, but can have one or more deviations from a true cylinder.

The term “coupled” is defined as connected, whether directly or indirectly through intervening components, and is not necessarily limited to physical connections. The connection can be such that the objects are permanently connected or releasably connected. The term “comprising” means “including, but not necessarily limited to”; it specifically indicates open-ended inclusion or membership in a so-described combination, group, series and the like.

The present invention implements lead zirconium titanate ceramic (PZT) that is operable to be formed as a transducer. The transducer is operable to be used in a droplet delivery device for humans and/or animals. Lead is indicated as reasonably anticipated to be a carcinogen. Therefore, it is important to prevent or limit contact of a liquid that will be introduced to the human and/or animal with the PZT transducer. The present technology presented herein removes the ability of lead in the PZT from leaching into the liquid that comes in contact with the PZT transducer in the droplet delivery device.

The present technology implements a wash of the PZT transducer with hydrochloric acid (HCl) solution. In one example, the PZT transducer is washed in a HCl solution for an hour. In some embodiments, the solution of HCl is 0.1 M (molar). In another embodiment the PZT is washed in an HCl 0.1 M solution for 24 hours at 60° C. Preferably a minimum of 1 mL of HCl solution is used per PZT. Once a PZT has been washed in 0.1 M HCl it is then batch washed with type 1 water 3 times. (Batch washing is adding room temp water to a beaker and filling to at least 1 mL per PZT. The beaker is then gently swirled and water dumped out, then the process is repeated a total of 3 times.) After all the residual acid is removed, the PZTs are set on a lint free cloth to dry at room temperature for 24 hours. This results in washing the lead that is capable of leaching into a surrounding fluid away from the PZT transducer. The performance of the PZT transducer is maintained even with the washing of the PZT transducer with HCl.

Once the PZT transducer is washed a coating can be added. The coating includes one or chemical substances that help prevent lead from leaching into fluid contacting the transducer, such as in droplet delivery devices. For example a coating of stainless steel can be added. In other examples, a polytetrafluorethylene (PTFE) coating can be implemented. In at least one example, the titanium oxide coating can have a thickness of about 300 nanometers. In still further embodiments, a coating for the PZT transducer can metals such as Titanium (Ti), Palladium (Pd), Platinum (Pt) and Gold (Au) in a thickness from about 10 nm to about 800 nm. In various embodiments, a coating comprising two or more chemical materials can be utilized for the PZT transducer, including combinations of the aforementioned compounds and metals, that help prevent lead from leaching into fluid.

The acid wash and coating results in helping to prevent lead leaching from the PZT transducer in undesirable amounts into the fluid that may be delivered in droplets, particularly to avoid such leaching where droplets are inhaled.

While the invention has been described with reference to exemplary embodiments, it will be understood by those skilled m the art that various changes may be made, and equivalents may be substituted for elements thereof without departing from the scope of the invention. In addition, many modifications may be made to adapt a particular situation or material to the teachings without departing from the essential scope thereof. Therefore, it is intended that the invention is not limited to the particular embodiment disclosed as the best mode contemplated for carrying out this invention, but that the invention will include all embodiments falling within the scope of the appended claims.

What is claimed is:

1. A method of treating a lead zirconium titanate ceramic transducer comprising:
washing the lead zirconium titanate ceramic transducer with an HCl solution; and
coating the transducer with one or more chemical substances that helps prevent lead from leaching into fluid contacting the transducer.

2. The method of claim 1, wherein the coating includes one or more of stainless steel, titanium oxide and polytetrafluorethylene.

3. The method of claim 1, wherein the coating includes titanium oxide and has a thickness of about 300 nm.

4. The method of claim 1, further comprising providing the transducer after said coating in a droplet delivery device.

5. The method of claim 4, wherein the HCl solution is about 0.1 M.

6. The method of claim 5, further comprising washing at about 60° C.

7. The method of claim 1, wherein the HCl solution is about 0.1 M.

8. The method of claim 7, further comprising washing at about 60° C.

9. The method of claim 2, further comprising batch washing the transducer with water after washing with HCl solution and drying the transducer prior to said coating.

10. The method of claim 9, wherein the HCl solution is about 0.1 M.

11. The method of claim of claim 1, wherein the coating includes one or metals selected from the group consisting of titanium, platinum, palladium, and gold and has a thickness of from about 10 nm to about 800 nm.

12. The method of claim of claim 4, wherein the coating includes one or metals selected from the group consisting of titanium, platinum, palladium, and gold and has a thickness of from about 10 nm to about 800 nm.

13. The method of claim 4, wherein the coating includes one or more of stainless steel, titanium oxide and polytetrafluorethylene.

14. The method of claim 4, wherein the coating includes at least two chemical substances selected from the group consisting of stainless steel, titanium oxide, polytetrafluorethylene, titanium, platinum, palladium, and gold.

15. The method of claim 1, wherein the coating includes at least two chemical substances selected from the group consisting of stainless steel, titanium oxide, polytetrafluorethylene, titanium, platinum, palladium, and gold.
